(19) United States
(12) Patent Application Publication
(10) Pub. No.: US 2023/0030450 A1
(43) Pub. Date: Feb. 2, 2023

(54) QUANTUM INTERFERENCE APPARATUS, ATOMIC OSCILLATOR, AND CONTROL METHOD

(71) Applicants: NEC Corporation, Tokyo (JP); NATIONAL INSTITUTE OF ADVANCED INDUSTRIAL SCIENCE AND TECHNOLOGY, Tokyo (JP)

(72) Inventors: Kenta Matsumoto, Tokyo (JP); Sota Kagami, Tokyo (JP); Shinya Yanagimachi, Ibaraki (JP); Atsuo Morinaga, Tokyo (JP); Takeshi Ikegami, Tokyo (JP)

(73) Assignees: NEC Corporation, Tokyo (JP); NATIONAL INSTITUTE OF ADVANCED INDUSTRIAL SCIENCE AND TECHNOLOGY, Tokyo (JP)

(21) Appl. No.: 17/877,235

(22) Filed: Jul. 29, 2022

(30) Foreign Application Priority Data
Aug. 2, 2021 (JP) 2021-126765

(51) Int. Cl. H03L 7/26

(52) U.S. Cl. CPC H03L 7/26

(57) ABSTRACT

A quantum interference apparatus includes a space and an alkali-metal atomic cell. A static magnetic field having a specific direction and a specific intensity is applied to the space. The alkali-metal atomic cell is disposed inside the space. Alkali-metal atoms are encapsulated in the alkali-metal atomic cell. As a static magnetic field is applied to the alkali-metal atomic cell and excitation light having at least two different frequency components is applied thereto, a quantum interference state of the alkali-metal atoms is formed. Among the frequency components of the excitation light, a frequency component that participates in the formation of the quantum interference state is light containing linearly-polarized lights having the same polarization direction as each other. The static magnetic field applied to the space is adjusted so that fluctuations of a transition frequency between ground levels forming the quantum interference state with respect to the magnetic field is suppressed.

### INCORPORATION BY REFERENCE

This application is based upon and claims the benefit of priority from Japanese patent application No. 2021-126765, filed on Aug. 2, 2021, the disclosure of which is incorporated herein in its entirety by reference.

### TECHNICAL FIELD

The present disclosure relates to a quantum interference apparatus, an atomic oscillator, and a control method.

### BACKGROUND ART

As oscillators having an accurate oscillation characteristic over a long period of time, atomic oscillators that oscillate based on the energy transition of alkali-metal atoms have been known. Regarding this technique, Japanese Unexamined Patent Application Publication No. 2014-053841 discloses an atomic cell module, a method for controlling the magnetic field of an atomic cell, and a quantum interference apparatus having high frequency stability using the atomic cell module and an electronic apparatus using the quantum interference apparatus.

In the technique disclosed in Japanese Unexamined Patent Application Publication No. 2014-053841, because of a problem in regard to the method for controlling the magnetic field and a problem in regard to the structure, it is difficult to obtain a quantum interference effect with high frequency stability against magnetic-field fluctuations.

The present disclosure has been made in view of the above-described problem, and an example object thereof is to provide a quantum interference apparatus, an atomic oscillator, and a control method capable of achieving a quantum interference effect with high frequency stability against magnetic-field fluctuations.

### SUMMARY

In a first example aspect, a quantum interference apparatus includes: a space to which a static magnetic field having a specific direction and a specific strength is applied; and an alkali-metal atomic cell disposed inside the space and encapsulating alkali-metal atoms therein, in which as the static magnetic field is applied to the alkali-metal atomic cell and excitation light having at least two different frequency components is applied thereto, a quantum interference state of the alkali-metal atoms is formed, among the frequency components of the excitation light, a frequency component that participates in the formation of the quantum interference state is light containing linearly-polarized lights having the same polarization direction as each other, and the static magnetic field is adjusted so that fluctuations of a resonance frequency with respect to the magnetic field are suppressed, the resonance frequency being a transition frequency between ground levels forming the quantum interference state.

Further, in another example aspect, an atomic oscillator includes a quantum interference apparatus, and a mechanism for adjusting an oscillating frequency based on the quantum interference state.

Further, in another example aspect, a control method includes: applying excitation light having at least two different frequency components to an alkali-metal atomic cell in which alkali-metal atoms are encapsulated; detecting light that has been transmitted through the alkali-metal atomic cell, and detecting a CPT resonance by measuring a spectrum of the transmitted light; and controlling a static magnetic field applied to the alkali-metal atomic cell so that fluctuations of a resonance frequency of the CPT resonance with respect to a magnetic field are suppressed.

According to the present disclosure, it is possible to provide a quantum interference apparatus, an atomic oscillator, and a control method capable of achieving a quantum interference effect with high frequency stability against magnetic-field fluctuations.

### BRIEF DESCRIPTION OF DRAWINGS

The above and other aspects, features and advantages of the present disclosure will become more apparent from the following description of certain example embodiments when taken in conjunction with the accompanying drawings, in which:

FIG. 1 shows an ultrafine structure of a cesium atom;

FIG. 2 is a schematic diagram of a CPT resonance that appears in a spectrum of transmitted light;

FIG. 3 shows an example of an excitation structure of a CPT resonance that is detected when circularly-polarized excitation light is incident;

FIG. 4 shows an example of an excitation structure of a CPT resonance that is detected when linearly-polarized excitation light is incident;

FIG. 5 shows dependences of resonance frequencies of (0, 0), (+1, −1) and (−1, +1) resonances on the magnetic field;

FIG. 6 is a functional block diagram of a quantum interference apparatus according to a first example embodiment;

FIG. 7 is a flowchart showing operations performed by the quantum interference apparatus according to the first example embodiment;

FIG. 8 is a functional block diagram of a quantum interference apparatus according to a second example embodiment;

FIG. 9 is a flowchart showing operations performed by the quantum interference apparatus according to the second example embodiment;

FIG. 10 is a functional block diagram of a quantum interference apparatus according to a third example embodiment;

FIG. 11 is a flowchart showing operations performed by the quantum interference apparatus according to the third example embodiment;

FIG. 12 is a structural diagram of an atomic oscillator according to a fourth example embodiment;

FIG. 13 shows a configuration of an atomic oscillator 120 according to a fifth example embodiment;

FIG. 14 is a schematic diagram showing a frequency spectrum of a frequency-modulated excitation light according to the fifth example embodiment;

FIG. 15 shows a dependence of a spectrum of transmitted light on the magnetic field that is detected when linearly-polarized excitation light is applied to an alkali-metal atomic cell according to the fifth example embodiment;

FIG. 16 shows a dependence of a resonance frequency of a CPT resonance on the magnetic field that is detected when linearly-polarized excitation light is applied to an alkali-metal atomic cell according to the fifth example embodiment;

FIG. 17 shows a dependence of a spectrum of transmitted light on the intensity of excitation light that is detected when linearly-polarized excitation light is applied to an alkali-metal atomic cell according to the fifth example embodiment;

FIG. 18 shows a dependence of an FWHM (Full Width at Half Maximum) of a CPT resonance on the intensity of excitation light that is detected when linearly-polarized excitation light is applied to an alkali-metal atomic cell according to the fifth example embodiment;

FIG. 19 shows a dependence of a spectrum of transmitted light on magnetic field that is detected when circularly-polarized excitation light is applied to an alkali-metal atomic cell;

FIG. 20 shows a dependence of a resonance frequency of a CPT resonance on the magnetic field that is detected when circularly-polarized excitation light is applied to an alkali-metal atomic cell; and

FIG. 21 is a functional block diagram of a quantum interference apparatus according to a sixth example embodiment.

### EXAMPLE EMBODIMENT

### Outline of Example Embodiment

An example embodiment will be described hereinafter in detail with reference to the drawings. Here, an outline of an example embodiment will be described before describing the example embodiment in detail.

There are several methods that are adopted in atomic oscillators, which are apparatuses for accurately measuring time. For example, there is an oscillating method using a quantum interference effect described hereinafter.

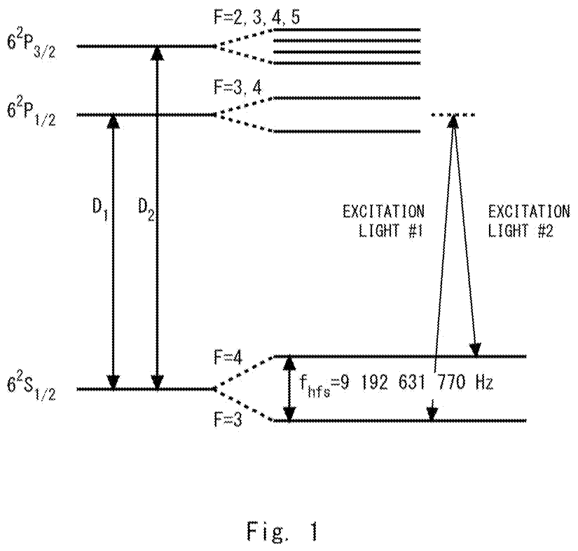

FIG. 1 shows an ultrafine structure of a cesium atom. As a result of a mutual interaction between the total angular momentum of electrons and the nuclear spin, a cesium atom, which is an alkali-metal atom, has ground levels of 6²S_{1/2}, excitation levels of 6²P_{1/2}, and excitation levels of 6²P_{3/2} as shown in FIG. 1. That is, in this case, the cesium atom has ground levels of 6²S_{1/2} having two levels of F=3 and 4, excitation levels of 6²P_{1/2} having two levels of F=3 and 4, and excitation levels of 6²P_{3/2} having four levels of F=2, 3, 4 and 5. The transition frequency between F=3 and F=4 of the ground levels 6²S_{1/2} among the aforementioned levels (i.e., the transition frequency between the ground levels) is defined as f_{hfs}=9 192 631 770 Hz in a state in which all the factors that cause fluctuations are eliminated. By using time information obtained from this frequency f_{hfs} it becomes possible to achieve a second based on the SI units (International System of Units). The transition frequency between the aforementioned ground states shifts (i.e., changes) due to factors such as a mutual interaction with an external electromagnetic field and collisions between cesium atoms and those of a buffer gas. In particular, a change in the transition frequency caused by a static magnetic field is called a Zeeman shift.

When cesium atoms at the ground levels are irradiated with resonance light having a frequency corresponding to the energy difference between these levels, in some cases the cesium atoms absorb the resonance light and their levels change to the excitation levels. Further, as a reverse process, in some cases, cesium atoms at the excitation levels emit resonance light and their levels change to the ground levels. It should be noted that resonance light having a frequency corresponding to the energy difference between the ground level of 6²S_{1/2} and the excitation level of 6²P_{1/2} is called a D₁ line, and resonance light having a frequency corresponding to the energy difference between the ground level of 6²S_{1/2} and the excitation level of 6²P_{3/2} is called a D₂ line.

In particular, three levels composed of the two ground levels of F=3 and 4 of 6²S_{1/2}, and one of the excitation levels of F=3 and 4 of 6²P_{1/2} are called Λ-type three levels because atoms at the three levels can perform a Λ-type transition by absorbing or emitting the D₁ line. A transition between the level of F=3 of 6²S_{1/2}, which is one of the levels constituting the Λ-type three levels, and one of the excitation levels of 6²P_{1/2}, which is one of the levels constituting the Λ-type three levels, is represented by a transition #1, and light having a frequency that closely resonates with the transition #1 is represented by excitation light #1. That is, the frequency of the excitation light #1 is equal to the transition frequency of the transition #1 or is different therefrom by a certain detuning frequency. Further, a transition between the level of F=4 of 6²S_{1/2}, which is one of the levels constituting the Λ-type three levels, and one of the excitation levels of 6²P_{1/2}, which is one of the levels constituting the Λ-type three levels, is represented by a transition #2, and light having a frequency that closely resonates with the transition #2 is represented by excitation light #2. That is, the frequency of the excitation light #2 is equal to the transition frequency of the transition #2 or is different therefrom by a certain detuning frequency. Here, it is assumed that these excitation lights (the excitation lights #1 and #2) are simultaneously applied to gaseous cesium atoms. Then, when the frequency difference between the applied excitation lights #1 and #2 coincides with the transition frequency between the two ground levels (F=3 of 6²S_{1/2} and F=4 of 6²S_{1/2}), a quantum coherence state (a dark resonance state) of the two ground levels is formed. As a result, a quantum interference effect (called CPT (Coherent Population Trapping)) that suppresses excitation to the excitation level occurs.

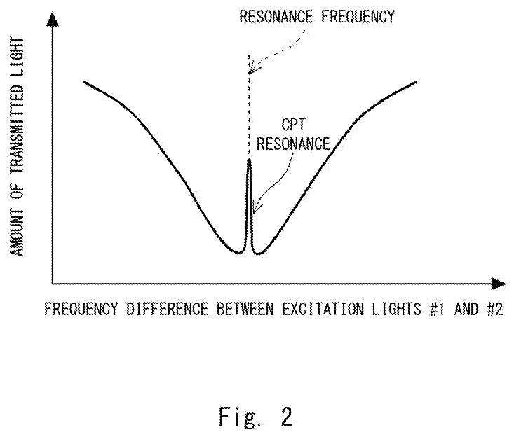

FIG. 2 is a schematic diagram of a CPT resonance that appears in the spectrum of transmitted light. For example, when the transmitted light of cesium atoms is detected and its spectrum is measured while sweeping the frequency difference between the excitation lights #1 and #2, the amount of the transmitted light reaches a peak value as shown in FIG. 2 and a CPT resonance is detected when the frequency difference coincides with the transition frequency between the ground levels. The frequency difference between the excitation lights in this state is called a resonance frequency. By detecting the resonance frequency of the CPT resonance and controlling the frequency difference between the excitation lights so that the resonance frequency (i.e., the frequency difference between the excitation lights) coincides with the transition frequency between the two ground levels, an accurate oscillator using a quantum interference effect is realized. Note that although the above description has been given by using cesium atoms as an example, similar atomic oscillators using the quantum interference effect can also be realized by using other alkali-metal atoms having similar atomic structures, such as rubidium atoms, sodium atoms, and potassium atoms.

In an atomic oscillator adopting the above-described CPT method, the resonance frequency of the CPT resonance is used as the base oscillating frequency. Note that in order to realize a precise atomic oscillator, it is necessary to take into account the Zeeman effect in which energy under a magnetic field changes according to the magnetic quantum number.

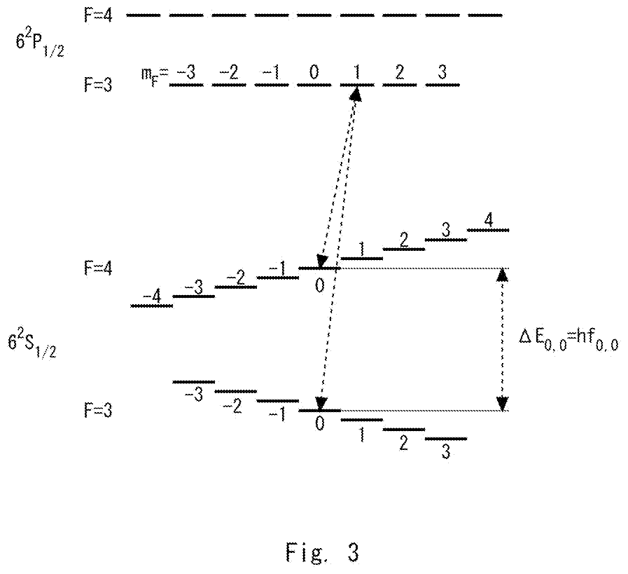

FIG. 3 shows an example of an excitation structure of a CPT resonance that is detected when circularly-polarized excitation light is incident. For example, when an external magnetic field is applied to cesium atoms, as a result of an energy shift by the Zeeman effect, the level of F=3 of 6²S_{1/2} splits into seven magnetic sub-levels having magnetic quantum numbers m_{F}=0, ±1, ±2 and ±3 as shown in FIG. 3. Further, the level of F=4 of 6²S_{1/2} splits into nine magnetic sub-levels having magnetic quantum numbers m_{F}=0, ±1, ±2, ±3 and ±4. As a result, since the transition frequencies between these magnetic sublevels are different from each other, a plurality of CPT resonances having different resonance frequencies can be detected in the state in which a magnetic field is applied to cesium atoms. Note that, for the sake of simplicity, the spectrum of transmitted light generated by a dark resonance state formed by a pair of magnetic sub-levels |F=3, m_{F}=i> and |F=4, m_{F}=j> is called an “(i, j) resonance”.

In general, in an atomic oscillator that is required to have high frequency stability, it is desirable to detect a CPT resonance of which fluctuations of the resonance frequency with respect to the magnetic field (i.e., fluctuations of the resonance frequency caused by the magnetic field) are small and to use the detected CPT resonance to control the oscillating frequency. For example, in the case of magnetic sub-levels |F=3, m_{F}=0> and |F=4, m_{F}=0>, neither of them produces the first-order Zeeman shift, so the energy shift caused by the application of a magnetic field is smaller than those that occur at the other magnetic sub-levels. Therefore, the (0, 0) resonance that occurs from the dark resonance state of them has been widely used in CPT-type atomic oscillators using cesium atoms. In FIG. 3, the (0, 0) resonance is indicated by a dashed arrow.

Further, in order to accurately determine a resonance frequency, it is desirable to detect a single CPT resonance while avoiding an increase in the linewidth of a resonance caused by overlapping of a plurality of CPT resonances. In general, in a CPT-type atomic oscillator, by applying a magnetic field to the alkali-metal atomic gas cell and thereby making an interval frequency in a plurality of resonance frequencies wider than the linewidth of the resonance, a non-overlapped single CPT resonance is detected. That is, in the CPT-type atomic oscillator, by applying a magnetic field to the alkali-metal atomic gas cell and thereby changing the resonance frequency, a non-overlapped single CPT resonance is detected.

Note that whether the dark resonance state can be formed between specific magnetic sub-levels is determined by the polarization state of the excitation light and the frequency components thereof. For example, the (0, 0) resonance that occurs from the dark resonance state having the excitation structure shown in FIG. 3 is detected when the excitation lights #1 and #2 are both circularly-polarized lights and have the same polarization states. Since other CPT resonances that can occur under this polarization condition are affected by the first-order Zeeman shift, it is possible to detect the non-overlapped (0, 0) resonance by applying a magnetic field of about several tens of μT (T: Tesla).

Further, a CPT-type atomic oscillator is provided with a magnetic-field correction device having a magnetic-field shielding function or a magnetic-field canceling function in order to avoid the fluctuations of the resonance frequency caused by higher-order Zeeman effects and to improve the frequency stability against magnetic-field fluctuations. Techniques relating to the above-described magnetic-field correction device are disclosed, for example, in Japanese Unexamined Patent Application Publication No. 2014-053841. However, the magnetic-field correction device disclosed in Japanese Unexamined Patent Application Publication No. 2014-053841 could not achieve sufficient performance. The reasons for the insufficient performance are as follows.

The first reason is that it is difficult to completely demagnetize the magnetic fields generated in the alkali-metal atoms by using the device for shielding external magnetic fields alone. For example, Japanese Unexamined Patent Application Publication No. 2014-053841 discloses a technique for demagnetizing in response to a detection signal from a magnetic detection unit. However, in the magnetic field correction using such a feedback system, it is difficult to cope with a magnetic field that changes in a time shorter than the time constant of the feedback. Therefore, it is difficult to completely demagnetize the magnetic fields generated in the alkali-metal atoms in the technique disclosed in Japanese Unexamined Patent Application Publication No. 2014-053841.

Further, the second reason is as follows. In some cases, a magnetic shield is provided in order to suppress the fluctuations of the external magnetic fields that occur in the place where the alkali-metal atomic gas cell is located. Note that in order to improve the magnetic-field shielding performance as described in Japanese Unexamined Patent Application Publication No. 2014-053841, it is necessary to provide a bulky magnetic shield, thus causing one of the factors due to which the reduction in the size of the atomic oscillator is limited. Therefore, in order to provide a small atomic oscillator, it is desirable that an atomic oscillator be provided with an oscillation mechanism having high frequency stability against the fluctuations of the external magnetic field.

A technique according to an example embodiment has been developed in view of the above-described problem in regard to the deterioration of the frequency stability of an atomic oscillator caused by fluctuations of external magnetic fields. That is, according to a technique in accordance with an example embodiment, it is possible to provide a quantum interference apparatus and an atomic oscillator using a quantum interference effect in which frequency stability against magnetic-field fluctuations generated inside an alkali-metal atomic gas cell is high.

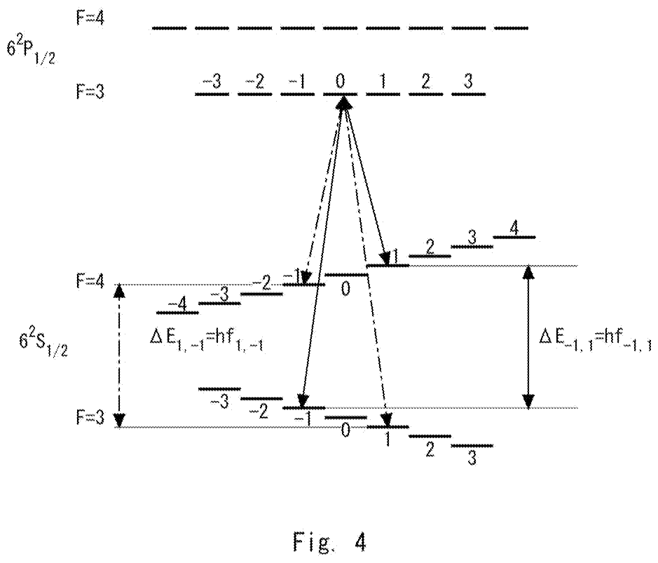

FIG. 4 shows an example of an excitation structure of a CPT resonance that is detected when linearly-polarized excitation light is incident. When a CPT resonance of cesium atoms is detected and excitation light is linearly-polarized light, the (0, 0) resonance is not detected, but the (+1, −1) resonance and the (−1, +1) resonance that occur from the dark resonance state having the excitation structure shown in FIG. 4 are detected. In FIG. 4, the (+1, −1) resonance is indicated by a dashed arrow and the (−1, +1) resonance is indicated by a solid arrow. Because both the magnetic sub-levels |F=3, m_{F}=+1> and |F=4, m_{F}=−1> produce roughly the same first-order Zeeman shifts, the fluctuations of the resonance frequency of the (+1, −1) resonance with respect to the magnetic field (i.e., fluctuations of the resonance frequency of the (+1, −1) resonance caused by the magnetic field) are roughly as small as those of the (0, 0) resonance. Similarly, the fluctuations of the resonance frequency of the (−1, +1) resonance with respect to the magnetic field are roughly as small as those of the (0, 0) resonance. Therefore, these CPT resonances can be used in CPT-type atomic oscillators. That is, this example embodiment is configured so that linearly-polarized excitation light is applied to alkali-metal electrons. Further, as will be described later, when linearly-polarized light is used as excitation light under a specific magnetic field, it is possible to detect a CPT resonance having higher stability of the resonance frequency against magnetic-field fluctuations as compared to that of the (0, 0) resonance that is detected when the excitation light is circularly-polarized light.

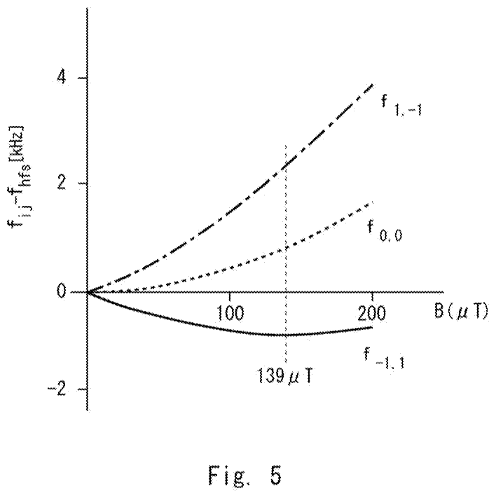

FIG. 5 shows the dependences of resonance frequencies of (0, 0), (+1, −1) and (−1, +1) resonances on the magnetic field. FIG. 5 shows the dependences of resonance frequencies of (0, 0), (+1, −1) and (−1, +1) resonances on the magnetic field, obtained from calculation of an energy difference between magnetic sub-levels of cesium atoms in which higher-order Zeeman shifts are also included. Note that a direction opposite to the traveling direction of the excitation light is defined as a positive direction of the applied magnetic field. Further, in FIG. 5, the magnetic-field dependence of the resonance frequency of the (0, 0) resonance is indicated by a dashed line, and the magnetic-field dependence of the resonance frequency of the (+1, −1) resonance is indicated by a chain line. Further, the magnetic-field dependence of the resonance frequency of the (−1, +1) resonance is indicated by a solid line.

Each of the shifts of the resonance frequencies caused by the external magnetic field (magnetic-field shifts; fluctuations of the resonance frequencies with respect to the magnetic field) is minimized at the magnetic field in which the resonance frequency has the minimum value. For example, in the (0, 0) resonance, the resonance frequency at which the gradient with respect to the external magnetic field is equal to or smaller than 1.2 Hz/μT is obtained in a range of the magnetic field from −15 μT to +15 μT. Similarly, in the (+1, 1) resonance, the resonance frequency at which the gradient with respect to the external magnetic field is equal to or smaller than 1.2 Hz/μT is obtained in a range of the magnetic field from −154 μT to +124 μT, and in the (−1, +1) resonance, the resonance frequency at which the gradient for the external magnetic field is equal to or smaller than 1.2 Hz/μT is obtained in a range of the magnetic field from −124 μT to +154 μT. In particular, in the (−1, +1) resonance, the shift of the resonance frequency is minimized when the magnetic field is +139 μT. Therefore, the detection of a non-overlapped CPT resonance in which the effect of the magnetic-field fluctuations is minimized is realized when the excitation light is linearly-polarized light and a specific static magnetic field determined according to the atomic type is applied to the alkali-metal atoms.

An atomic oscillator according to this example embodiment includes a space to which a static magnetic field of which the strength can be controlled is applied, an alkali-metal atomic cell in which alkali-metal atoms are encapsulated, and linearly-polarized excitation light having at least two frequency components that enter the alkali-metal atomic cell, the frequency difference of which (i.e., the difference between the frequencies of the two components) is substantially equal to the transition frequency between the ground states. The alkali-metal atomic cell is disposed at a predetermined place inside the space to which the static magnetic field is applied.

Further, a quantum interference apparatus according to this example embodiment includes a space to which a static magnetic field having a specific direction and a specific strength is applied, an alkali-metal atomic cell in which alkali-metal atoms are encapsulated, and excitation light having at least two frequency components that enter the alkali-metal atomic cell, the frequency difference of which (i.e., the difference between the frequencies of the two components) is substantially equal to the transition frequency between the ground states. Note that the alkali-metal atomic cell is disposed so that its internal space is located in the space to which the static magnetic field is applied. Further, the quantum interference apparatus is an apparatus that forms a quantum interference state of alkali-metal atoms by applying excitation light to the alkali-metal atoms. Further, among the frequency components of the excitation light, a frequency component(s) that participates in the formation of the quantum interference state is light containing linearly-polarized lights having the same polarization direction as each other, and the quantum interference apparatus includes a magnetic-field generation device for suppressing the fluctuations of the transition frequency between the ground levels forming the quantum interference state for the magnetic-field changes (i.e., a magnetic-field generation device for suppressing the fluctuations of the transition frequency caused by the changes of the magnetic field).

It should be noted that, in the detection of a CPT resonance by the technique according to this example embodiment, the fluctuations of the resonance frequency for the fluctuations of the external magnetic field (i.e., the fluctuations of the resonance frequency caused by the fluctuations of the external magnetic field) are reduced. Therefore, it is possible to provide a quantum interference apparatus and an atomic oscillator having high frequency stability against magnetic-field fluctuations. In the example shown in FIG. 5, it is possible to provide a quantum interference apparatus and an atomic oscillator having high frequency stability against the fluctuations of external magnetic fields by applying a magnetic field (139 μT) in which the stability of the resonance frequency of the (−1, +1) resonance against magnetic-field fluctuations is the highest to the alkali-metal atomic cell.

### First Example Embodiment

An example embodiment will be described hereinafter with reference to the drawings. The following description and the drawings are partially omitted and simplified as appropriate for clarifying the explanation. Further, the same elements are denoted by the same reference numerals (or symbols) throughout the drawings, and redundant descriptions thereof are omitted as appropriate.

### [Description of Configuration]

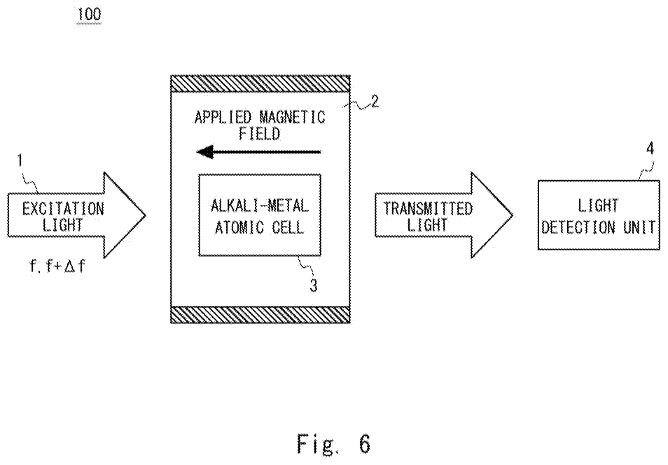

FIG. 6 is a functional block diagram of a quantum interference apparatus 100 according to a first example embodiment. The quantum interference apparatus 100 according to this example embodiment includes excitation light 1, a space 2, an alkali-metal atomic cell 3, and a light detection unit 4. The excitation light 1 has at least two different frequency components. A static magnetic field substantially parallel to the incident direction of the excitation light 1 is applied to the space 2. That is, the space 2 functions as a magnetic-field application space. Further, a static magnetic field in a direction opposite to the incident direction of the excitation light 1 (the opposing direction) can be applied to the space 2. Note that a static magnetic field in a direction that is same as the incident direction of the excitation light 1 may be applied to the space 2. That is, a static magnetic field parallel to a direction that is opposite to or same as the incident direction of the excitation light 1 may be applied to the space 2. Alkali-metal atoms are encapsulated in the alkali-metal atomic cell 3. Further, the alkali-metal atomic cell 3 is disposed at a predetermined place inside the space 2. The light detection unit 4 detects light (transmitted light) that has been transmitted through (i.e., has passed through) the alkali-metal atomic cell 3.

As described above, the excitation light 1 has at least two different frequency components. Further, although the excitation light 1 may have three or more different frequency components, the frequency difference between two of these frequency components is roughly equal to the transition frequency between the two magnetic sub-levels forming the dark resonance state of the alkali-metal atoms. The frequency difference of the excitation light 1 can preferably be realized by a mechanism capable of sweeping the frequency difference in a range of about 1 MHz. Note that the sweeping range may not be about 1 MHz as long as a resonance can be detected. For example, the sweeping range may be narrower than 1 MHz and may be, for example, about 10 kHz. Further, the two frequency components which are contained in the excitation light 1 and of which the frequency difference is roughly equal to the transition frequency between the ground levels of the alkali-metal atoms are light containing linearly-polarized lights whose polarization directions are the same as each other. For example, when light having a certain frequency contained in the excitation light 1 is linearly-polarized light, it is sufficient if light having a frequency that is different from that of the linearly-polarized light by a frequency equivalent to the transition frequency between the ground levels of the alkali-metal atoms is contained in the excitation light 1 and this light has a polarization component parallel to the linearly-polarized light. That is, the excitation light 1 has polarization components parallel to each other, and has two frequency components of which frequency difference is roughly equal to the transition frequency between the ground levels of the alkali-metal atoms. The excitation light 1 that satisfies these conditions is obtained, for example, by modulating light having a single wavelength emitted from a semiconductor laser or the like by a frequency roughly equal to ½ of the transition frequency between the ground levels and thereby generating a sideband thereof. Alternatively, the excitation light 1 that satisfies these conditions can be obtained, for example, by combining two lights each having a single wavelength emitted from two semiconductor lasers or the like having a mechanism for controlling the frequency difference therebetween.

The space 2 to which a static magnetic field is applied includes an area including the internal space of the alkali-metal atomic cell 3. For example, it is possible to control the direction and the strength of the static magnetic field applied to the space 2 by disposing a coil so as to cover the alkali-metal atomic cell 3 inside the space 2 and adjusting the position and shape of the coil and adjusting the direction and magnitude of the current applied to the coil. In this way, a static magnetic field having a specific direction and a specific strength is applied to the space 2.

Alkali-metal atoms having Λ-type three levels are encapsulated in the alkali-metal atomic cell 3. The alkali-metal atoms encapsulated in the alkali-metal atomic cell 3 may be, for example, any of cesium atoms, rubidium atoms, sodium atoms, and potassium atoms. The material of which the container of the alkali-metal atomic cell 3 is made is preferably a transparent material, such as glass, which has a high transmittance for the excitation light 1. In addition to the alkali-metal atoms, a buffer gas that does not contribute to the absorption of the excitation light 1 may be encapsulated in the alkali-metal atomic cell 3 for the purpose of reducing the effect of collisions of gaseous alkali-metal atoms with the wall surface of the container. Further, a temperature control device that does not block the optical path of the excitation light 1 may be provided in the alkali-metal atomic cell 3 for the purpose of controlling the saturation vapor pressure of the gaseous alkali-metal atoms. The temperature control device is formed by, for example, a resistance heating heater.

The excitation light 1 enters the alkali-metal atomic cell 3, and a part of the light entered therein has been transmitted through (i.e., has passed through) the alkali-metal atomic cell 3. The light detection unit 4 includes an apparatus that detects the light that has been transmitted through the alkali-metal atomic cell 3 (i.e., the transmitted light). The light detection unit 4 is realized, for example, by using a photodiode(s). The light detection unit 4 can be realized by a photodetector (i.e., light detector) which serves as light detection means.

Note that the quantum interference apparatus 100 is an apparatus that forms a quantum interference state of alkali-metal atoms by applying the excitation light 1 to the alkali-metal atoms. Further, among the frequency components of the excitation light 1, a frequency component(s) that participates in the formation of the quantum interference state is light which contains linearly-polarized lights having the same polarization direction and of which the frequency difference coincides with the transition frequency between the ground states. Further, the quantum interference apparatus 100 may include a magnetic-field generation device (corresponding to a later-described static magnetic-field application device 8) for suppressing the fluctuations of the transition frequency between the ground levels forming the quantum interference state for the magnetic-field changes (i.e., a magnetic-field generation device for suppressing the fluctuations of the transition frequency caused by the changes of the magnetic field). The magnetic-field generation device can be provided in the space 2.

### [Description of Operation]

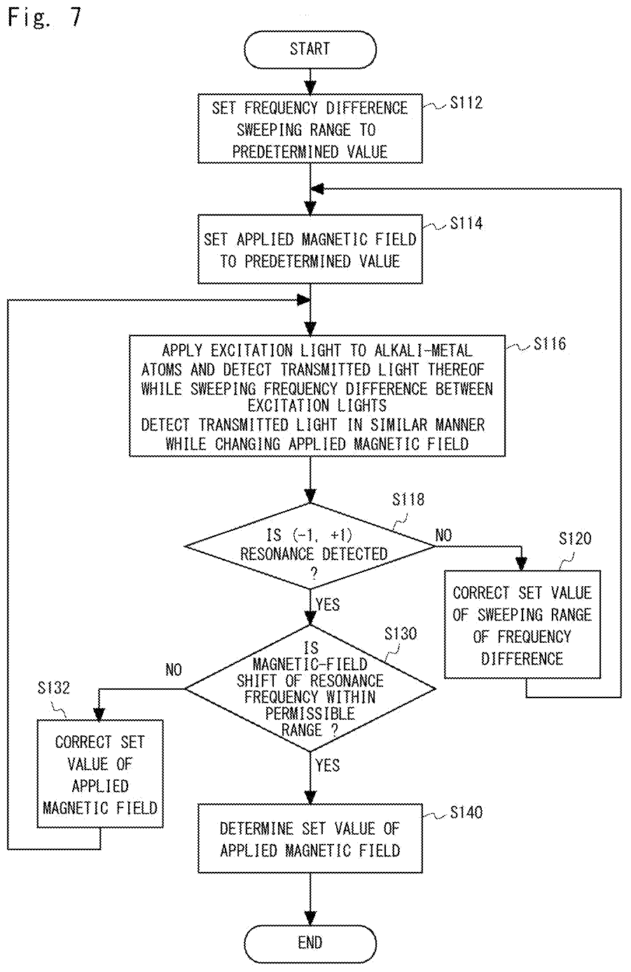

FIG. 7 is a flowchart showing operations performed by the quantum interference apparatus 100 according to the first example embodiment. The flowchart shown in FIG. 7 shows a control method (an adjustment method and a detection method) performed by the quantum interference apparatus 100 according to the first example embodiment. The operations shown in FIG. 7 may be carried out by a control device (e.g., control means such as a later-described control device 20) provided in the quantum interference apparatus 100 according to the first example embodiment. The operations in this example embodiment will be described with reference to the flowchart shown in FIG. 7.

When a quantum interference effect (a CPT resonance) is detected, transmitted light of the excitation light 1 is detected while sweeping the frequency difference thereof (S112 to S116). Firstly, the sweeping range of the frequency difference of the excitation light 1 is set to a predetermined value (i.e., a predetermined range) (Step S112). Specifically, the quantum interference apparatus 100 sets the sweeping range of the frequency difference of the excitation light 1 to a range that includes the resonance frequency of the CPT resonance and is wider than the FWHM (Full Width at Half Maximum) of the CPT resonance. The quantum interference apparatus 100 preferably sets the sweeping range of the frequency difference of the excitation light 1 to a range in which both the (−1, +1) and (+1, −1) resonances are expected to be detected. Next, the strength of the magnetic field applied to the alkali-metal atomic cell 3 (the applied magnetic field) is set to a predetermined value (Step S114). Specifically, the quantum interference apparatus 100 sets the strength of the magnetic field applied to the alkali-metal atomic cell 3 to a value at which the magnetic-field shift of the resonance frequency (i.e., the fluctuations of the resonance frequency with respect to the magnetic field (i.e., caused by the magnetic field)) of the (−1, +1) resonance is expected to be the smallest. This value can be calculated from the Zeeman effect that occurs in the magnetic sub-levels, and is, for example, 139 μT as shown in FIG. 5 when the alkali-metal atoms encapsulated in the alkali-metal atomic cell 3 are cesium atoms.

Under this condition, the quantum interference apparatus 100 applies the excitation light 1 to the alkali-metal atomic cell 3 and detects the transmitted light thereof while sweeping the frequency difference of the excitation light 1 (Step S116). Then, the quantum interference apparatus 100 changes the applied magnetic field and detects the transmitted light in a similar manner. Specifically, the quantum interference apparatus 100 applies the excitation light 1 to the alkali-metal atomic cell 3 and detects the transmitted light thereof by the light detection unit 4, and by doing so, measures the spectrum of the transmitted light and detects a CPT resonance. Then, in order to evaluate the magnetic-field shift of the resonance frequency, the quantum interference apparatus 100 slightly changes the applied magnetic field, for example, changes the applied magnetic field by about 10 μT, and detects the transmitted light in a similar manner. In this way, it is possible to detect a CPT resonance in which the resonance frequency is stable (i.e., the magnetic-field shift is small) against the fluctuations of the external magnetic field.

The quantum interference apparatus 100 determines whether or not the (−1, +1) resonance has been detected from the obtained spectrum of the transmitted light (Step S118). When the linearly-polarized excitation light 1 is applied to alkali-metal electrons, the (−1, +1) and (+1, −1) resonances in which the shift of the resonance frequency caused by the magnetic field is small are detected. Therefore, it is possible to determine whether or not the (−1, +1) resonance has been detected from these resonance frequencies.

When the (−1, 1) resonance has not been detected (No in Step S118), the quantum interference apparatus 100 corrects the set value of the sweeping range (i.e., the set sweeping range) of the frequency difference (Step S120). Then, the processing flow returns to the step S114. Specifically, the quantum interference apparatus 100 extends the sweeping range of the frequency difference, sets the applied magnetic field again (S114), and detects the transmitted light, i.e., measures the spectrum of the transmitted light again (S116).

On the other hand, when the (−1, 1) resonance has been detected (Yes in Step S118), the quantum interference apparatus 100 determines whether or not the magnetic-field shift of the resonance frequency is within a permissible range (Step S130). That is, the quantum interference apparatus 100 determines whether or not the magnetic-field shift for the resonance frequency is suppressed. Specifically, the quantum interference apparatus 100 determines whether or not the magnitude of the shift of the resonance frequency caused by the magnetic field is within a permissible range, e.g., is no larger than 1.2 Hz/μT. That is, it is determined whether or not the gradient of the resonance frequency with respect to the applied magnetic field (which corresponds to the magnetic-field shift) is within a predetermined range. The predetermined range is, for example, “no smaller than −1.2 Hz/μT and no larger than 1.2 Hz/μT”. Alternatively, the predetermined range may be, for example, “no smaller than −10 Hz/μT and no larger than 10 Hz/μT”.

When the magnitude of the magnetic-field shift of the resonance frequency is outside the permissible range (No in Step S130), the quantum interference apparatus 100 corrects the set value of the applied magnetic field (Step S132). Then, the processing flow returns to the step S116. Specifically, when the magnetic-field shift of the resonance frequency is positive (i.e., 0<1.2 Hz/μT<“magnetic-field shift”), the quantum interference apparatus 100 resets the applied magnetic field to a smaller value. Further, when the magnetic-field shift of the resonance frequency is negative (i.e., 0>−1.2 Hz/μT>“magnetic-field shift”), the quantum interference apparatus 100 resets the applied magnetic field to a larger value. Then, the quantum interference apparatus 100 detects the transmitted light, i.e., measures the spectrum of the transmitted light again (S116).

On the other hand, when the magnitude of the magnetic-field shift of the resonance frequency is within the permissible range (Yes in Step S130), the quantum interference apparatus 100 determines the set value of the applied magnetic field (Step S140). Then, the adjustment of the applied magnetic field is finished. By the above-described process, the static magnetic field applied to the space 2 is adjusted so that the magnetic-field shift for the transition frequency (the resonance frequency) between the ground levels forming the quantum interference state is suppressed. Further, the magnetic field applied to the space 2 (the alkali-metal atomic cell 3) is controlled based on the spectrum of the transmitted light, for example, by the control device (the control means). Further, the applied magnetic field is controlled, for example, by the control device (the control means) so that the gradient of the resonance frequency with respect to the applied magnetic field (which corresponds to the magnetic-field shift) falls within the predetermined range. As a result, the frequency difference of the excitation light is controlled, thus making it possible to form the quantum interference state of the alkali-metal atoms. This fact also applies to other example embodiments.

### [Description of Effect]

According to the quantum interference apparatus 100 in accordance with the first example embodiment, by generating an applied magnetic field adjusted by the above-described method at a place inside the alkali-metal atomic cell, it is possible to detect a CPT resonance in which the resonance frequency is stable against the fluctuations of external magnetic fields. Further, by performing feedback control on the frequency difference of the excitation light so that the frequency difference is locked at the detected resonance frequency, it is possible to provide an atomic oscillator having high frequency stability against the fluctuations of external magnetic fields. That is, by realizing an atomic oscillator having a mechanism for adjusting the oscillating frequency of the excitation light (the frequency difference of the excitation light) based on the resonance frequency (the quantum interference effect) detected by the quantum interference apparatus 100, it is possible to provide an atomic oscillator having high frequency stability against the fluctuations of external magnetic fields. In other words, it is possible to control (to perform feedback control for) the frequency difference of the excitation light based on the spectrum of the transmitted light detected by the light detection unit 4 (the photodetector) and thereby to form a quantum interference state of alkali-metal atoms.

### Second Example Embodiment

Next, a second example embodiment will be described. The following description and the drawings are partially omitted and simplified as appropriate for clarifying the explanation. Further, the same elements are denoted by the same reference numerals (or symbols) throughout the drawings, and redundant descriptions thereof are omitted as appropriate.

### [Description of Configuration]

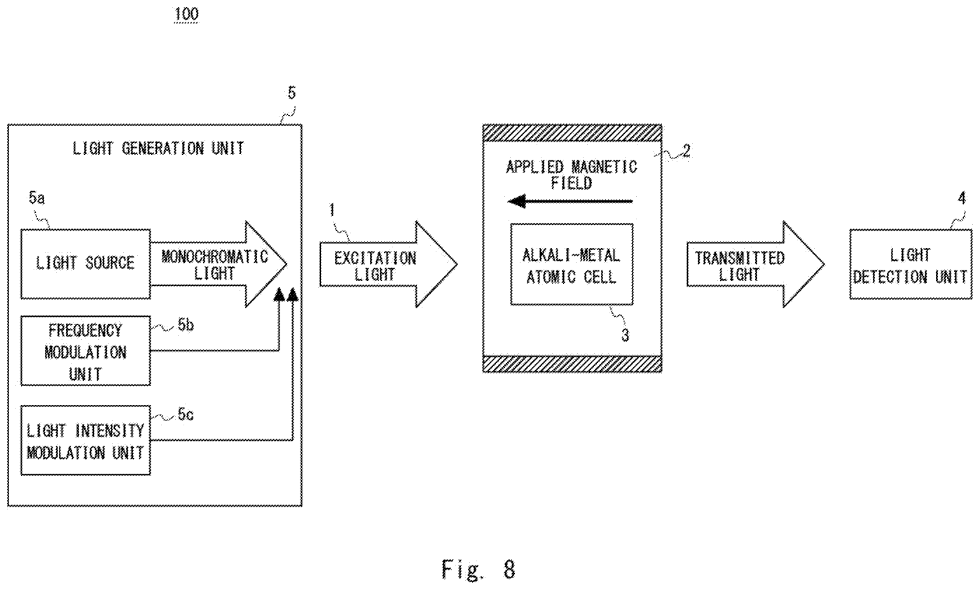

FIG. 8 is a functional block diagram of a quantum interference apparatus 100 according to the second example embodiment. The quantum interference apparatus 100 according to the second example embodiment includes excitation light 1, a light generation unit 5 that generates the excitation light 1, a space 2, an alkali-metal atomic cell 3, and a light detection unit 4. The excitation light 1, the space 2, the alkali-metal atomic cell 3, and the light detection unit 4 are substantially the same as those in the first example embodiment, and therefore descriptions thereof will be omitted.

The light generation unit 5 functions as light generation means. The light generation unit 5 generates excitation light 1 having at least two frequency components. The light generation unit 5 has a mechanism capable of modulating the light amount (i.e., light intensity) of the excitation light, and is realized by, for example, a voltage-controllable optical attenuator (i.e., light generator). The light generation unit 5 includes a light source 5a, a frequency modulation unit 5b, and a light intensity modulation unit 5c. The light source 5a outputs monochromatic light. The frequency modulation unit 5b modulates the frequency of the monochromatic light output from the light source 5a. The light intensity modulation unit 5c modulates the light intensity of the monochromatic light output from the light source 5a. The excitation light 1 is generated as the frequency and light intensity of the monochromatic light output from the light source 5a are modulated. Further, the light generation unit 5 is configured to modulate the intensity of the excitation light. The light generation unit 5 can be controlled by a control device (e.g., control means such as a later-described control device 20) provided in the quantum interference apparatus 100.

### [Description of Operation]

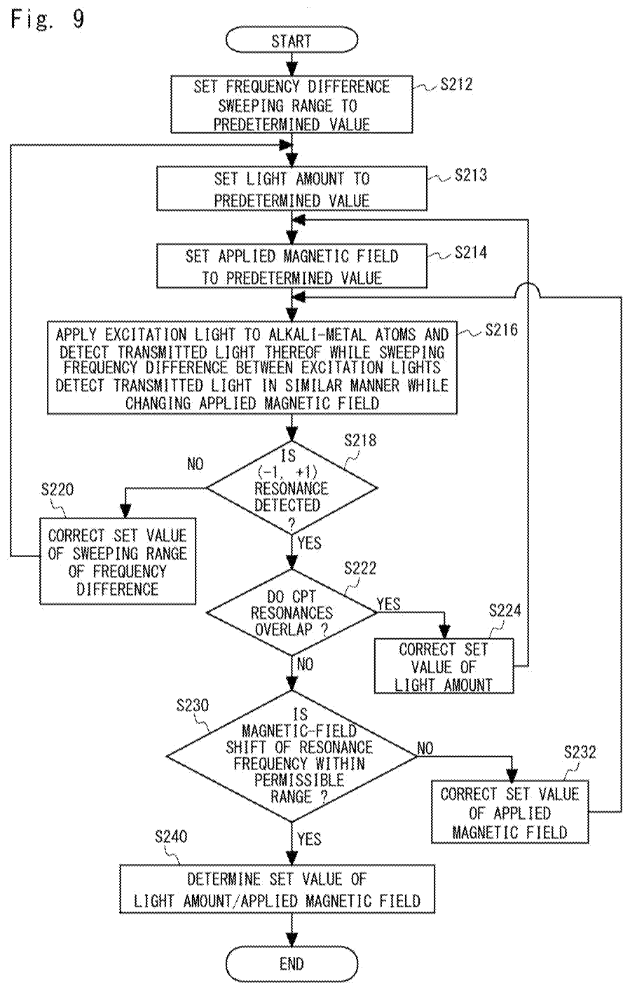

FIG. 9 is a flowchart showing operations performed by the quantum interference apparatus 100 according to the second example embodiment. The flowchart shown in FIG. 9 shows a control method (an adjustment method and a detection method) performed by the quantum interference apparatus 100 according to the second example embodiment. The operations shown in FIG. 9 may be carried out by a control device (e.g., control means such as a later-described control device 20) provided in the quantum interference apparatus 100 according to the second example embodiment. The operations in the second example embodiment will be described with reference to the flowchart shown in FIG. 9.

When a quantum interference effect (a CPT resonance) is detected, transmitted light of the excitation light 1 is detected while sweeping the frequency difference thereof (S212 to S216). Firstly, similarly to the step S112 in FIG. 7, the quantum interference apparatus 100 sets the sweeping range of the frequency difference of the excitation light 1 to a predetermined value (i.e., a predetermined range) (Step S212). Further, the quantum interference apparatus 100 sets the light amount of the excitation light 1 to a predetermined value (Step S213). Specifically, the quantum interference apparatus 100 sets the light amount of the excitation light 1 to the predetermined value by controlling the light generation unit 5. Further, similarly to the step S114 in FIG. 7, the quantum interference apparatus 100 sets the strength of the magnetic field applied to the alkali-metal atomic cell 3 (the applied magnetic field) to a predetermined value (Step S214).

Similarly to the step S116 in FIG. 7, under this condition, the quantum interference apparatus 100 applies the excitation light 1 to the alkali-metal atomic cell 3 and detects the transmitted light thereof while sweeping the frequency difference of the excitation light 1 (Step S216). Then, the quantum interference apparatus 100 changes the applied magnetic field and detects the transmitted light in a similar manner. That is, the quantum interference apparatus 100 applies the excitation light 1 generated by the light generation unit 5 to the alkali-metal atomic cell 3 and detects the transmitted light thereof by the light detection unit 4, and by doing so, measures the spectrum of the transmitted light. Then, in order to evaluate the magnetic-field shift of the resonance frequency, the quantum interference apparatus 100 slightly changes the applied magnetic field and detects the transmitted light in a similar manner.

Similarly to the step S118 in FIG. 7, the quantum interference apparatus 100 determines whether or not the (−1, +1) resonance has been detected from the obtained spectrum of the transmitted light (Step S218). When the (−1, 1) resonance has not been detected (No in Step S218), the quantum interference apparatus 100 corrects the set value of the sweeping range (i.e., the set sweeping range) of the frequency difference as in the step S120 in FIG. 7 (Step S220). Then, the processing flow returns to the step S213, and a CPT resonance is detected again.

On the other hand, when the (−1, +1) resonance has been detected (Yes in Step S218), the quantum interference apparatus 100 determines whether or not another CPT resonance overlaps the detected CPT resonance (Step S222). Specifically, the quantum interference apparatus 100 determines whether or not the (−1, +1) and (+1, −1) resonances overlap each other from the obtained spectrum of the transmitted light.

When the CPT resonances overlap each other (Yes in Step S222), the quantum interference apparatus 100 corrects the set value of the light amount (Step S224). Then, the processing flow returns to the step S214. Specifically, the quantum interference apparatus 100 reduces the light amount of the excitation light 1, sets the applied magnetic field again (S214), and detects the transmitted light, i.e., measures the spectrum of the transmitted light again (S216).

On the other hand, when the CPT resonances do not overlap each other, i.e., the (−1, +1) resonance has been detected without any other resonance overlapping thereon (No in Step S222), the quantum interference apparatus 100 determines whether or not the magnetic-field shift of the resonance frequency is within a permissible range as in the step S130 in FIG. 7 (Step S230). When the magnitude of the magnetic-field shift of the resonance frequency is outside the permissible range (No in Step S230), the quantum interference apparatus 100 corrects the set value of the applied magnetic field as in the step S132 in FIG. 7 (Step S232). Then, the processing flow returns to the step S216. That is, the quantum interference apparatus 100 detects the transmitted light, i.e., measures the spectrum of the transmitted light again (S216).

On the other hand, when the magnitude of the magnetic-field shift of the resonance frequency is within the permissible range (Yes in Step S230), the quantum interference apparatus 100 determines the set values of the light amount and the applied magnetic field (Step S240). Then, the adjustment of the light amount and the applied magnetic field is finished. By the above-described process, the static magnetic field applied to the space 2 is adjusted so that the magnetic-field shift for the transition frequency (the resonance frequency) between the ground levels forming the quantum interference state is suppressed. Further, the light amount for the excitation light is adjusted so that two or more of CPT resonances do not overlap each other. The light amount of the excitation light can be controlled based on the spectrum of the transmitted light thereof by, for example, the control device (the control means).

### [Description of Effect]

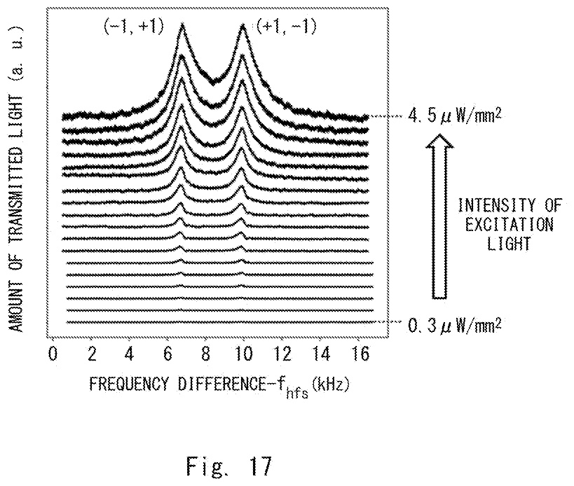

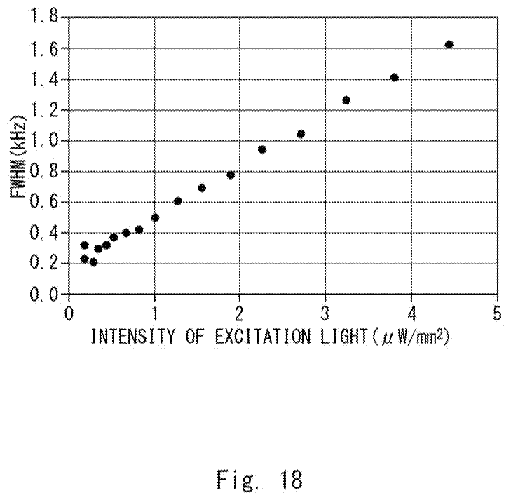

According to the quantum interference apparatus 100 in accordance with the second example embodiment, by adjusting the magnetic field applied to the alkali-metal atomic cell 3 and the light amount of the excitation light 1 applied to the alkali-metal atomic cell 3, the CPT resonance in which the resonance frequency is stable against the fluctuations of external magnetic fields is detected without any other resonance overlapping thereon. As an effect of this detection, by performing feedback control on the frequency difference so that the frequency difference is locked at the detected resonance frequency, it is possible to provide an atomic oscillator having high frequency stability against the fluctuations of external magnetic fields. That is, by controlling (performing feedback control for) the light amount of the excitation light based on the spectrum of the transmitted light detected by the light detection unit 4, a CPT resonance in which the resonance frequency is stable against the fluctuations of external magnetic fields can be realized without any other resonance overlapping thereon. For example, as shown in FIGS. 17 and 18 (which will be described later), it is possible, when the frequency difference of the excitation light is swept in a frequency range separated (i.e., different) from the resonance frequency of the optical absorption characteristic obtained by the quantum interference effect by an amount equivalent to the FWHM of the optical absorption characteristic or smaller, to realize a state in which the quantum interference effect produced from only one set of magnetic sub-levels contributes to the spectrum of the transmitted light.

### Third Example Embodiment

Next, a third example embodiment will be described. The following description and the drawings are partially omitted and simplified as appropriate for clarifying the explanation. Further, the same elements are denoted by the same reference numerals (or symbols) throughout the drawings, and redundant descriptions thereof are omitted as appropriate.

### [Description of Configuration]

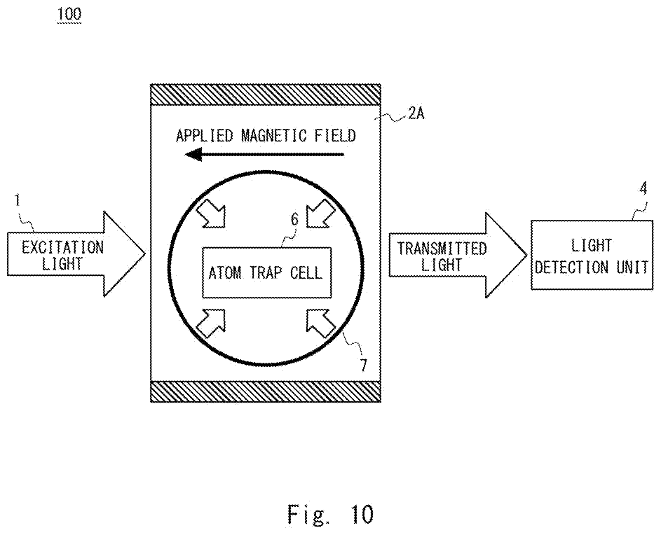

FIG. 10 is a functional block diagram of a quantum interference apparatus 100 according to the third example embodiment. The quantum interference apparatus 100 according to the third example embodiment includes an optical trapping system. Further, the quantum interference apparatus 100 according to the third example embodiment includes excitation light 1, a magnetic-field generation device 2A, an atom trap cell 6, a magneto-optical trap system 7, and a light detection unit 4.

Similarly to the above-described example embodiments, the excitation light 1 has at least two different frequency components. Gaseous alkali-metal atoms are encapsulated in the atom trap cell 6. The excitation light 1 is applied to the atom trap cell 6. The magnetic-field generation device 2A applies a static magnetic field to a predetermined place inside the atom trap cell 6.

The atom trap cell 6 corresponds to the alkali-metal atomic cell 3. Similar to the alkali-metal atomic cell 3, alkali-metal atoms having Λ-type three levels are encapsulated in the atom trap cell 6. The alkali-metal atoms encapsulated in the atom trap cell 6 may be, for example, any of cesium atoms, rubidium atoms, sodium atoms and potassium atoms. The material of which the container of the atom trap cell 6 is made is preferably a transparent material, such as glass, which has a high transmittance for the excitation light 1 and for the light for trapping atoms.

The magneto-optical trap system 7 generates cooled atoms inside the atom trap cell 6. The magneto-optical trap system 7 functions as an optical trapping system for trapping atoms by light. The magneto-optical trap system 7 traps alkali-metal atoms, for example, by applying an optical electric field and a trapping magnetic field for trapping atoms in the atom trap cell 6. The light detection unit 4 detects light that has been transmitted through (i.e., has passed through) the atom trap cell 6 (i.e., transmitted light).

As compared to the quantum interference apparatuses 100 according to the above-described example embodiments, in the quantum interference apparatus 100 according to the third example embodiment, the effect on the quantum interference effect caused by the collisions between alkali-metal atoms and the inner wall of the cell, other alkali-metal atoms or the buffer gas is extremely small. This is because the kinetic speeds of atoms optically-trapped in the atom trap cell 6 are extremely low compared to those of the atoms in the alkali-metal atomic cell, so that the number of collisions per time (i.e., per unit time) is small. Therefore, in the third example embodiment, a more accurate quantum interference apparatus 100 can be realized.

### [Description of Operation]

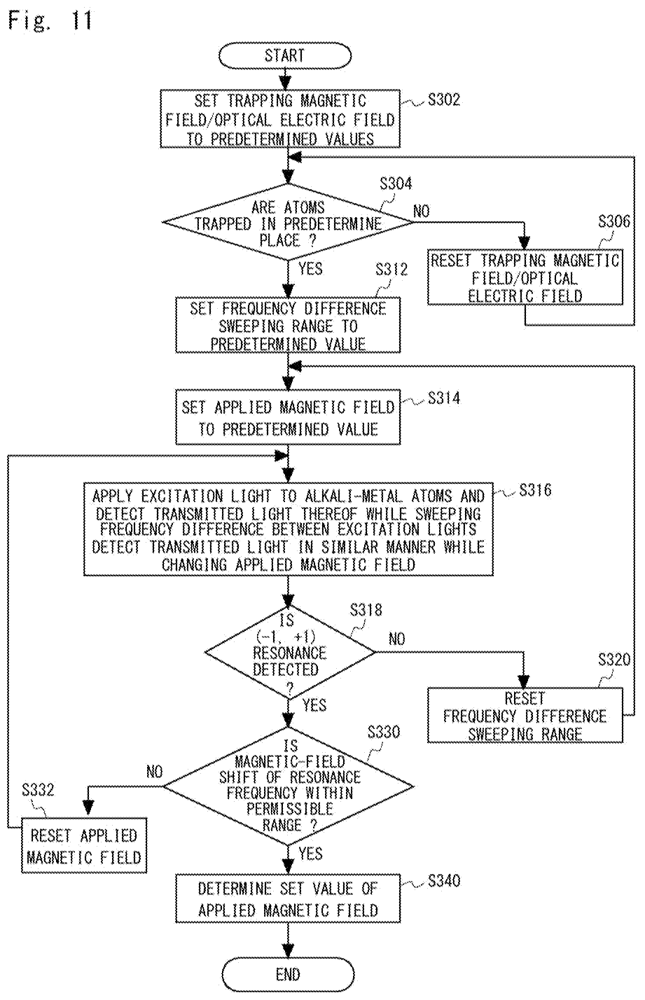

FIG. 11 is a flowchart showing operations performed by the quantum interference apparatus 100 according to the third example embodiment. The flowchart shown in FIG. 11 shows a control method (an adjustment method and a detection method) performed by the quantum interference apparatus 100 according to the third example embodiment. The operations shown in FIG. 11 may be carried out by a control device (e.g., control means such as a later-described control device 20) provided in the quantum interference apparatus 100 according to the third example embodiment. The operations in this example embodiment will be described with reference to the flowchart shown in FIG. 11.

Firstly, the quantum interference apparatus 100 sets a trapping magnetic field and an optical electric field to predetermined values (Step S302). Specifically, the quantum interference apparatus 100 sets the optical electric field and the trapping magnetic field of the magneto-optical trap system 7 so that alkali-metal atoms are trapped in a predetermined place inside the atom trap cell 6.

The quantum interference apparatus 100 determines whether or not alkali-metal atoms have been trapped in the predetermined place (Step S304). When alkali-metal atoms have not been trapped in the predetermined place (No in Step S304), the quantum interference apparatus 100 resets the trapped magnetic field and the optical electric field (Step S306). Then, the processing flow returns to the step S304. That is, the processes in the steps S304 and S306 are repeated until alkali-metal atoms are trapped in the predetermined place.

On the other hand, when alkali-metal atoms have been trapped in the predetermined place (Yes in Step S304), the quantum interference apparatus 100 sets the sweeping range of the frequency difference of the excitation light 1 to a predetermined value (step S312) as in the step S112 in FIG. 7 and the like. Further, similarly to the step S114 in FIG. 7 and the like, the quantum interference apparatus 100 sets the strength of the magnetic field applied to the alkali-metal atomic cell 3 (the applied magnetic field) to a predetermined value (step S314).

Under these conditions, the quantum interference apparatus 100 detects transmitted light (detects a CPT resonance) (Step S316). Specifically, the quantum interference apparatus 100 temporarily cancels the trapping optical electric field and the trapping magnetic field, and applies the excitation light 1 to the atom trap cell 6 and detects the transmitted light thereof while sweeping the frequency difference of the excitation light 1. Then, the quantum interference apparatus 100 changes the applied magnetic field and detects the transmitted light in a similar manner. That is, after trapping cooled atoms in the predetermined place, the quantum interference apparatus 100 temporarily cancels the trapping optical electric field and the trapping magnetic field, applies the excitation light 1 to the atom trap cell 6, detects the transmitted light thereof by the light detection unit 4, and thereby measures the spectrum of the transmitted light. In this way, the quantum interference apparatus 100 detects the CPT resonance.

Similarly to the step S118 in FIG. 7 and the like, the quantum interference apparatus 100 determines whether or not the (−1, +1) resonance has been detected from the obtained spectrum of the transmitted light (Step S318). When the (−1, 1) resonance has not been detected (No in Step S318), the quantum interference apparatus 100 corrects the set value of the sweeping range (i.e., the set sweeping range) of the frequency difference as in the step S120 in FIG. 7 and the like (Step S320). Then, the processing flow returns to the step S314, and a CPT resonance is detected again.

On the other hand, when the (−1, 1) resonance has been detected (Yes in Step S318), the quantum interference apparatus 100 determines whether or not the magnetic-field shift of the resonance frequency is within a permissible range as in the step S130 in FIG. 7 and the like (Step S330). When the magnitude of the magnetic-field shift of the resonance frequency is outside the permissible range (No in Step S330), the quantum interference apparatus 100 corrects the set value of the applied magnetic field as in the step S132 in FIG. 7 and the like (Step S332). Then, the processing flow returns to the step S316. That is, the quantum interference apparatus 100 detects the transmitted light, i.e., measures the spectrum of the transmitted light again (S316).

On the other hand, when the magnitude of the magnetic-field shift of the resonance frequency is within the permissible range (Yes in Step S330), the quantum interference apparatus 100 determines the set value of the applied magnetic field (Step S340). Then, the adjustment of the applied magnetic field applied to the atom trap cell 6 is finished. By the above-described process, the static magnetic field applied to the space 2 is adjusted so that the magnetic-field shift for the transition frequency (the resonance frequency) between the ground levels forming the quantum interference state is suppressed. Note that although FIG. 11 corresponds to one that is obtained by correcting the processing flow according to the first example embodiment, the configuration according to the third example embodiment is not limited to such a configuration. The third example embodiment can be applied not only to the first example embodiment but also to the second example embodiment. That is, the light amount may be adjusted in the third example embodiment.

### [Description of Effect]

According to the quantum interference apparatus 100 in accordance with the third example embodiment, by detecting a CPT resonance by using cooled atoms formed by the magneto-optical trap system 7, it is possible to ignore the fluctuations of the resonance frequency of the CPT resonance and the fluctuations of the width of a signal line(s) caused by the effect of the buffer gas. Therefore, as an effect of the quantum interference apparatus 100 according to the third example embodiment, it is possible to detect a CPT resonance in which the stability of the resonance frequency is higher and the linewidth of the resonance is narrower than those in the case where an alkali-metal atomic cell containing a buffer gas is used. Therefore, it is possible to provide a quantum interference apparatus 100 (an atomic oscillator) having high frequency stability against magnetic-field fluctuations.

### Fourth Example Embodiment

Next, a fourth example embodiment will be described. The following description and the drawings are partially omitted and simplified as appropriate for clarifying the explanation. Further, the same elements are denoted by the same reference numerals (or symbols) throughout the drawings, and redundant descriptions thereof are omitted as appropriate.

### [Description of Configuration]

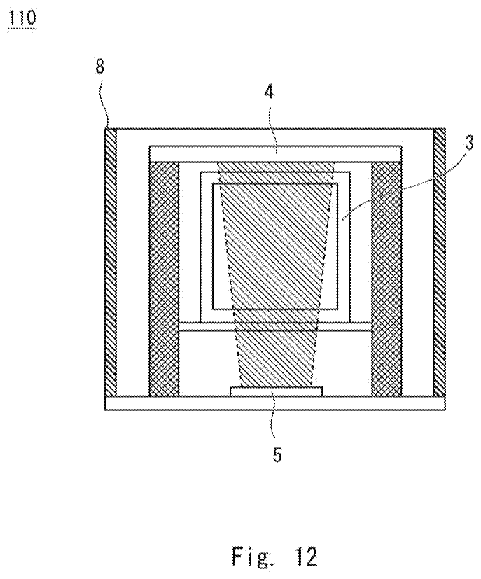

FIG. 12 is a structural diagram of an atomic oscillator 110 according to the fourth example embodiment. The atomic oscillator 110 shown in FIG. 12 is a small atomic oscillator including a simplified magnetic-field shielding device (having a simplified magnetic-field shielding function). The atomic oscillator 110 includes a light generation unit 5 that forms excitation light, an alkali-metal atomic cell 3 disposed on the optical path of the excitation light, a light detection unit 4 that detects light that has been transmitted through (i.e., has passed through) the alkali-metal atomic cell 3, and a static magnetic-field application device 8. Note that a magnetic-field shielding device (not shown) having a simplified magnetic-field shielding function is provided so as to cover the outside of the static magnetic-field application device 8. Further, the atomic oscillator 110 can be included (i.e., provided) in the above-described quantum interference apparatus 100. In other words, the above-described quantum interference apparatus 100 can include the atomic oscillator 110.

The light generation unit 5 generates excitation light having at least two frequency components. Note that the two frequency components which are contained in the excitation light and of which the frequency difference is roughly equal to the transition frequency between the ground levels of the alkali-metal atoms are linearly-polarized lights having the same polarization direction. The excitation light can be generated, for example, by a light source, such as a semiconductor laser, that oscillates (i.e., emits) linearly-polarized light. For example, a sideband is generated by driving a semiconductor laser with a frequency-modulated current, so that linearly-polarized excitation light having at least two frequency components is obtained.

Alkali-metal atoms having Λ-type three levels are encapsulated in the alkali-metal atomic cell 3. As described above, the alkali-metal atoms encapsulated in the alkali-metal atomic cell 3 may be, for example, any of cesium atoms, rubidium atoms, sodium atoms, and potassium atoms. The alkali-metal atomic cell 3 is made of, for example, a transparent material, such as glass, which has a high transmittance for the excitation light. In addition to the alkali-metal atoms, a buffer gas that does not contribute to the absorption of the excitation light may be encapsulated in the alkali-metal atomic cell 3 for the purpose of reducing the effect of collisions of gaseous alkali-metal atoms with the wall surface of the container. Further, the alkali-metal atomic cell 3 may include a temperature control mechanism that has such a shape that the optical path of the excitation light is not blocked, or is made of a transparent material having a high transmittance for the excitation light.

The light detection unit 4 detects light (transmitted light) that has been transmitted through (i.e., has passed through) the alkali-metal atomic cell 3. That is, the light detection unit 4 includes an apparatus that detects light that has been transmitted through (i.e., has passed through) the alkali-metal atomic cell 3. The light detection unit 4 is realized, for example, by using a photodiode(s). The light detection unit 4 can be formed by a photodetector which serves as light detection means.

The static magnetic-field application device 8 applies a static magnetic field to a predetermined place inside the alkali-metal atomic cell 3. The static magnetic-field application device 8 can be realized, for example, by disposing a coil so as to cover the alkali-metal atomic cell 3. The static magnetic-field application device 8 may correspond to the magnetic-field generation device 2A according to the third example embodiment.

Note that similarly to the above-described example embodiments, the quantum interference apparatus 100 can be realized by a light generation unit 5, an alkali-metal atomic cell 3, and a light detection unit 4. Further, the atomic oscillator 110 may include a mechanism for adjusting the oscillating frequency based on the quantum interference effect (CPT) detected by a method according to any of the above-described example embodiments. That is, the atomic oscillator 110 may include a quantum interference apparatus 100 and a mechanism for adjusting the oscillating frequency based on the quantum interference effect (CPT).

### [Description of Effect]

According to the atomic oscillator 110 in accordance with the fourth example embodiment, it is possible to adjust the magnetic field applied to the inside of the alkali-metal atomic cell 3 so that the effect of the fluctuations of the external magnetic field on the quantum interference effect is suppressed by the method described in any of the above-described example embodiments. In this way, a CPT resonance in which the fluctuations of the resonance frequency with respect to the fluctuations of the external magnetic field is minimized is detected. Note that in the case where a CPT resonance on which any other resonance does not overlap is detected, when the (−1, 1) resonance is used, the fluctuations of the resonance frequency with respect to the external magnetic field is small as compared to the case where the (0, 0) resonance is used. Therefore, when it is assumed that there is a permissible range for the fluctuations of the frequency, the magnetic-field range corresponding to this range is wider for the (−1, 1) resonance than for the (0, 0) resonance. Therefore, the permissible range for the magnetic-field fluctuations at the predetermined place inside the alkali-metal atomic cell 3, which is set in order to ensure a certain frequency stability, is widened. Therefore, in this example embodiment, since high magnetic-field shielding capability is not required, a simple magnetic shield having a low shielding factor (a low magnetic-field shielding performance index) can be used. Further, when the environmental magnetic field is small, the magnetic shield can be removed (i.e., becomes unnecessary). Therefore, the magnetic shield can be removed or simplified, and the size of the atomic oscillator 110 can be reduced.

### Fifth Example Embodiment

Next, a fifth example embodiment will be described. The following description and the drawings are partially omitted and simplified as appropriate for clarifying the explanation. Further, the same elements are denoted by the same reference numerals (or symbols) throughout the drawings, and redundant descriptions thereof are omitted as appropriate. As the fifth example embodiment, an example of an atomic oscillator capable of detecting a quantum interference effect is shown.

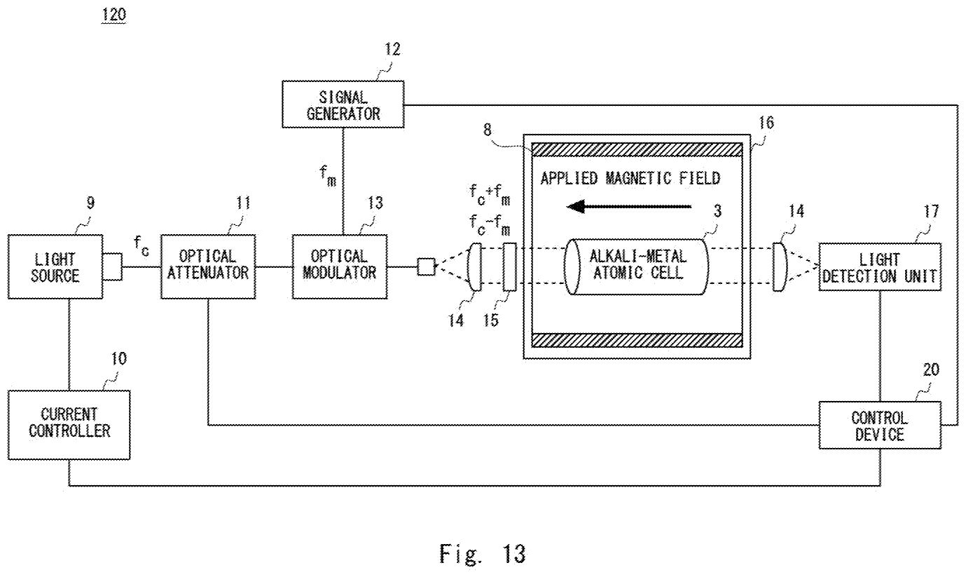

FIG. 13 shows a configuration of an atomic oscillator 120 according to the fifth example embodiment. A method for detecting a quantum interference effect will be described with reference to FIG. 13. The atomic oscillator 120 according to the fifth example embodiment includes a light source 9, a current controller 10, an optical attenuator 11, a signal generator 12, an optical modulator 13, a collimating lens 14, a λ/2 plate 15, a magnetic-field shielding device 16, a light detection unit 17, and a control device 20. The magnetic-field shielding device 16 includes an alkali-metal atomic cell 3 and a static magnetic-field application device 8.

The control device 20 may be implemented, for example, by a computer.

Therefore, the control device 20 includes, as a hardware configuration, an arithmetic unit such as a processor, a storage device such as a memory or a disk, a communication unit, and a UI (User Interface). The control device 20 controls the operations of the current controller 10, the optical attenuator 11, and the signal generator 12. The control device 20 may control the operations of the current controller 10, the optical attenuator 11, and the signal generator 12 according to the result of the detection by the light detection unit 17. Further, the control device 20 may control the static magnetic-field application device 8 according to the result of the detection by the light detection unit 17. The light detection unit 17 can be realized by a photodetector which serves as light detection means.

The current controller 10 outputs a driving current to the light source 9, for example, under the control of the control device 20. The light source 9 emits laser light having a frequency f_{c} according to this driving current. For example, the light source 9 emits single-wavelength laser light having a carrier wavelength of 894.593 nm. The optical attenuator 11 is, for example, a variable optical attenuator. The optical attenuator 11 attenuates the laser light emitted from the light source 9, for example, under the control of the control device 20. The optical attenuator 11 modulates the amplitude of the laser light emitted from the light source 9. In this way, laser light having an arbitrary optical intensity is generated.

The signal generator 12 outputs a modulation signal having a frequency fₘ to the optical modulator 13, for example, under the control of the control device 20. The optical modulator 13 optically modulate the laser light output from the optical attenuator 11 by combining the modulation signal therewith. In this way, a sideband of the laser light having the frequency f_{c} is formed. This light output from the optical modulator 13 serves as excitation light.

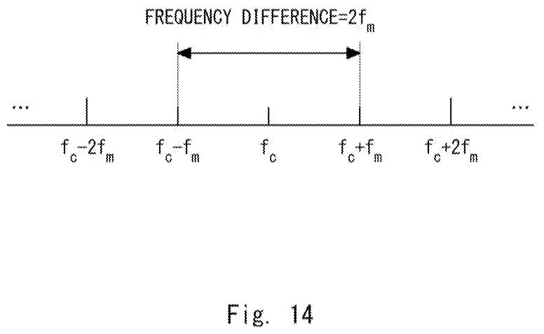

FIG. 14 is a schematic diagram showing a frequency spectrum of frequency-modulated excitation light. As shown in FIG. 14, sidebands f_{c}-fₘ and f_{c}+fₘ of the laser light having the frequency f_{c} are formed by the above-described frequency modulation. The frequency difference between the two sidebands is 2fₘ. In this way, excitation light having two frequency components of which the frequency difference is 2fₘ is generated. For example, by adjusting the frequency fₘ of the modulation signal to about 4.596 GHz, excitation light having two frequency components of which the frequency difference is about 9.192 GHz is generated.

The excitation light generated by the optical modulator 13 propagates through an optical fiber. Under the above-described conditions, the excitation light, which has propagated through the optical fiber, is collimated by the collimating lens 14. For example, the excitation light becomes laser light having a beam diameter of about 7 mm through the collimating lens 14. Further, the collimated laser light (the excitation light) becomes linearly-polarized light as the laser light passes through the λ/2 plate 15, which functions as a polarizing plate. The linearly-polarized excitation light is applied to the alkali-metal atomic cell 3 provided in the magnetic-field shielding device 16. For example, cesium atoms, which are used as alkali-metal atoms, and a nitrogen gas having a pressure of 1.33 kPa, which is used as a buffer gas, are encapsulated in the alkali-metal atomic cell 3. Further, the alkali-metal atomic cell 3 is formed as, for example, a cylindrical cell having a diameter of 20 mm and a height of 20 mm. The static magnetic-field application device 8 applies a static magnetic field to the inside of the alkali-metal atomic cell 3. The static magnetic field is applied to the alkali-metal atomic cell 3 in a direction roughly parallel to the optical path of the excitation light. Further, in order to improve the stability of the magnetic field, the alkali-metal atomic cell 3 is disposed inside the magnetic-field shielding device 16 formed by (i.e., formed as) a magnetic-field shielding container. The light (the laser light) that has been transmitted through (i.e., has passed through) the alkali-metal atomic cell 3 converges through the collimating lens 14 and is detected by the light detection unit 17. As a result, the control device 20 acquires the light amount of the light (the laser light) that has been transmitted through the alkali-metal atomic cell 3. For example, the light detection unit 17 may measure the light amount of the laser light (the transmitted light) and transmit information indicating the light amount to the control device 20.

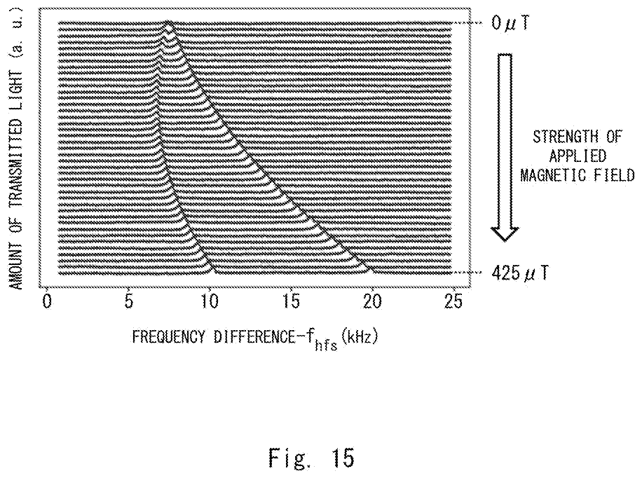

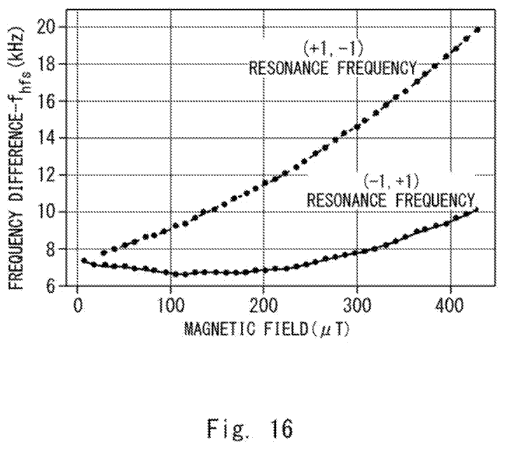

FIG. 15 shows the dependence of the spectrum of transmitted light on the magnetic field that is detected when linearly-polarized excitation light is applied to the alkali-metal atomic cell 3 according to the fifth example embodiment. Further, FIG. 16 shows the dependence of the resonance frequency of the CPT resonance on the magnetic field that is detected when linearly-polarized excitation light is applied to the alkali-metal atomic cell 3 according to the fifth example embodiment. Further, FIG. 17 shows the dependence of the spectrum of transmitted light on the intensity of the excitation light that is detected when linearly-polarized excitation light is applied to the alkali-metal atomic cell 3 according to the fifth example embodiment. Further, FIG. 18 shows the dependence of the FWHM (Full Width at Half Maximum) of the CPT resonance on the intensity of the excitation light that is detected when linearly-polarized excitation light is applied to the alkali-metal atomic cell 3 according to the fifth example embodiment.

The control device 20 controls the signal generator 12 while keeping the applied magnetic field constant, and the amount of the transmitted light is measured by the light detection unit 17 while sweeping the frequency difference of the excitation light. Further, the amount of the transmitted light is measured in a similar manner while changing the strength of the applied magnetic field from 0 μT to 425 μT. In this way, as shown in FIG. 15, two CPT resonances corresponding to the (−1, +1) and (+1, −1) resonances are detected.

Further, as shown in FIG. 16, in the range of the magnetic field in which the applied magnetic field is 425 μT or smaller, each of the resonance frequencies of the (−1, +1) and (+1, −1) resonances satisfactorily coincides with the calculation of the magnetic-field dependence of the resonance frequency shown in FIG. 5. In particular, regarding the resonance frequency of the (−1, +1) resonance shown in FIG. 16, when a magnetic field of 139 μT is applied, the gradient of the magnetic-field shift (of the resonance frequency) with respect to the applied magnetic field becomes zero (i.e., the magnetic-field shift (the shift of the resonance frequency) becomes the smallest) as in the case of FIG. 5. Note that the frequency difference from the frequency of f_{hfs}=9 192 631 770 Hz at the magnetic field of 0 μT is caused by a frequency shift that is caused by the encapsulation of the buffer gas (nitrogen).

Note that when a CPT resonance is used in an atomic oscillator, the shift of the resonance frequency with respect to the applied magnetic field affects the frequency stability against the fluctuations of the external magnetic field. Note that when the (−1, +1) resonance is used for the frequency oscillation in a state in which a static magnetic field of 139 μT is applied, the amount of the shift of the resonance frequency becomes 9.2 Hz or smaller and the gradient of the magnetic field of the resonance frequency becomes 1.2 Hz/μT or smaller for the magnetic-field fluctuation of 15 μT. From the above-described facts, by the method described in the above-described example embodiment, it is possible to provide a quantum interference apparatus and an atomic oscillator having high frequency stability against magnetic-field fluctuations.

Further, when a CPT resonance is used for a frequency oscillation, it is preferred to detect a signal composed of a single CPT resonance in order to improve the frequency stability. As shown in FIG. 16, when a static magnetic field of 139 μT is applied, the resonance frequencies of the (−1, +1) and (+1, −1) resonances are separated (i.e., different) from each other by 3.10 kHz. In order to detect these resonances separately from each other, it is preferred that the FWHM of the CPT resonance is smaller than ½ of the resonance frequency difference. For example, by controlling the power broadening which originates from the light intensity of the excitation light, it is possible to adjust the linewidth of the CPT resonance.

Further, when a static magnetic field of 139 μT is applied, the light intensity of the excitation light is changed by controlling the optical attenuator 11 and thereby a CPT resonance is detected, the linewidth (the FWHM) of the CPT resonance increases as the light intensity increases as shown in FIG. 17. Note that, in the example shown in FIG. 17, the intensity of the excitation light is changed from 0.3 μW/mm² to 4.5 μW/mm², and for each of the light intensities, the amount of the transmitted light is measured by the light detection unit 17 while sweeping the frequency difference of the excitation light.

Further, in this example embodiment, for example, as shown in FIG. 18, it is possible to detect a CPT resonance having a FWHM of 1.5 kHz or lower by setting the light intensity of the excitation light applied to the alkali-metal atomic cell 3 to about 4 μW/mm² or lower. As a result of this detection, by the method shown in the above-described second example embodiment, it is possible to provide a quantum interference apparatus having higher frequency stability. That is, it is possible, when the frequency difference of the excitation light is swept in a frequency range separated (i.e., different) from the resonance frequency of the optical absorption characteristic obtained by the quantum interference effect by an amount equivalent to the FWHM of the optical absorption characteristic or smaller, to realize a state in which the quantum interference effect produced from only one set of magnetic sub-levels contributes to the spectrum of the transmitted light.

Note that, in this example embodiment, linearly-polarized excitation light is applied to the alkali-metal atomic cell 3. A case where circularly-polarized excitation light is applied to the alkali-metal atomic cell 3 by disposing a λ/4 plate in addition to the λ/2 plate 15 on the optical path of the excitation light will be described hereinafter.

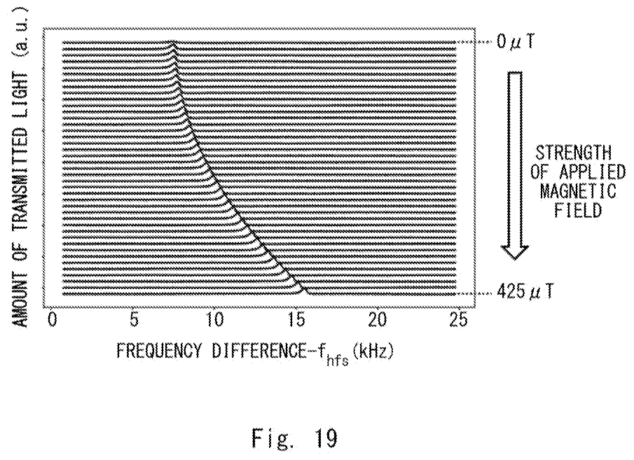

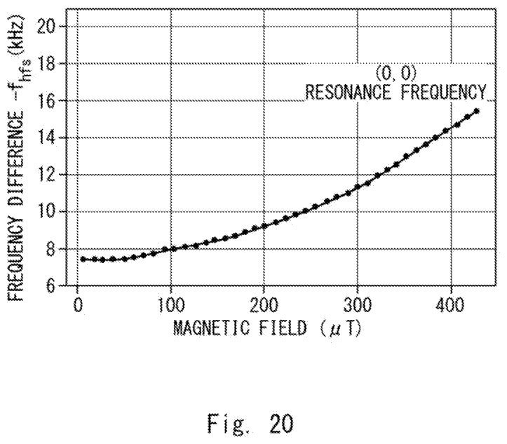

FIG. 19 shows the dependence of the spectrum of transmitted light on the magnetic field that is detected when circularly-polarized excitation light is applied to the alkali-metal atomic cell 3. Further, FIG. 20 shows the dependence of the resonance frequency of a CPT resonance on the magnetic field that is detected when circularly-polarized excitation light is applied to the alkali-metal atomic cell 3. When circularly-polarized excitation light is applied to the alkali-metal atomic cell 3, the (0, 0) resonance is detected as shown in FIG. 19. Further, in this case, as shown in FIG. 20, the fluctuations of the resonance frequency with respect to the applied magnetic field can be approximated by a quadratic function (i.e., represented by a quadratic function in an approximated manner). Then, when the applied magnetic field is 0 μT, the gradient of the resonance frequency with respect to the applied magnetic field becomes zero. This result satisfactorily coincides with the calculation of the magnetic-field dependence of the resonance frequency of the (0, 0) resonance shown in FIG. 5. However, at or around 0 μT, a CPT resonance(s) between higher-order magnetic sub-levels overlaps, and the linewidth of the detected resonance signal is strongly affected by the fluctuations of the external magnetic field, so that it is not suitable for the frequency oscillation. Therefore, it is preferred that linearly-polarized excitation light is applied to the alkali-metal atomic cell 3.

### Sixth Example Embodiment

Next, a sixth example embodiment will be described. The following description and the drawings are partially omitted and simplified as appropriate for clarifying the explanation. Further, the same elements are denoted by the same reference numerals (or symbols) throughout the drawings, and redundant descriptions thereof are omitted as appropriate.

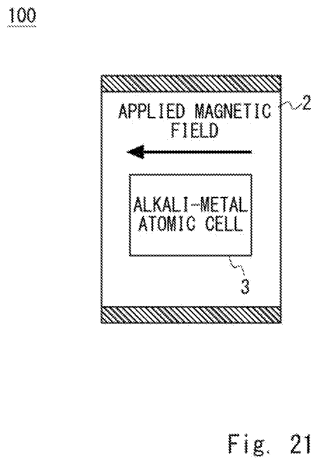

FIG. 21 is a functional block diagram of a quantum interference apparatus 100 according to the sixth example embodiment. The quantum interference apparatus 100 according to the sixth example embodiment includes a space 2 and an alkali-metal atomic cell 3. A static magnetic field having a specific direction and a specific strength is applied to the space 2. The alkali-metal atomic cell 3 is disposed inside the space 2. Further, alkali-metal atoms are encapsulated in the alkali-metal atomic cell 3.

Note that as the static magnetic field is applied to the alkali-metal atomic cell 3 and excitation light having at least two different frequency components is applied thereto, a quantum interference state of the alkali-metal atoms is formed. Further, among the frequency components of the excitation light, a frequency component that participates in the formation of the quantum interference state contains linearly-polarized lights which have the same polarization direction as each other and of which the frequency difference coincides with the transition frequency between the ground states. Further, the static magnetic field applied to the space 2 is adjusted so that the shift of the resonance frequency, which is the transition frequency between the ground levels forming the quantum interference state, with respect to the magnetic field (magnetic-field shift) is suppressed. By the above-described configuration, the quantum interference apparatus 100 according to the sixth example embodiment can realize a quantum interference effect in which the frequency stability against magnetic-field fluctuations is high.

### Modified Example

Note that the present disclosure is not limited to the above-described example embodiments, and they may be modified as necessary without departing from the scope and spirit of the disclosure. For example, any two or more of the above-described example embodiments may be applied to each other. Further, in the flowcharts shown in FIGS. 7, 9 and 11, the order of processes can be changed as appropriate. Further, in each of the flowcharts, one or more of a plurality of processes may be omitted.

Further, the processes shown in each of the flowcharts may be implemented by, for example, an information processing apparatus such as a computer (such as the control device 20). Note that the information processing apparatus (such as the control device 20) includes an arithmetic unit such as a CPU (Central Processing Unit) and a storage device such as a memory or a disk. For example, the processes shown in each of the flowcharts may be implemented by having the arithmetic unit execute a program stored in the storage device.

The program includes instructions (or software codes) that, when loaded into a computer, cause the computer to perform one or more of the functions described in the embodiments. The program may be stored in a non-transitory computer readable medium or a tangible storage medium. By way of example, and not a limitation, non-transitory computer readable media or tangible storage media can include a random-access memory (RAM), a read-only memory (ROM), a flash memory, a solid-state drive (SSD) or other types of memory technologies, a CD-ROM, a digital versatile disc (DVD), a Blu-ray disc or other types of optical disc storage, and magnetic cassettes, magnetic tape, magnetic disk storage or other types of magnetic storage devices. The program may be transmitted on a transitory computer readable medium or a communication medium. By way of example, and not a limitation, transitory computer readable media or communication media can include electrical, optical, acoustical, or other forms of propagated signals.

The whole or part of the example embodiments disclosed above can be described as, but not limited to, the following supplementary notes.

### (Supplementary Note 1)

A quantum interference apparatus comprising:

a space to which a static magnetic field having a specific direction and a specific strength is applied; and

an alkali-metal atomic cell disposed inside the space and encapsulating alkali-metal atoms therein, wherein

as the static magnetic field is applied to the alkali-metal atomic cell and excitation light having at least two different frequency components is applied thereto, a quantum interference state of the alkali-metal atoms is formed,

among the frequency components of the excitation light, a frequency component that participates in the formation of the quantum interference state is light containing linearly-polarized lights having the same polarization direction as each other, and

the static magnetic field is adjusted so that fluctuations of a resonance frequency with respect to the magnetic field are suppressed, the resonance frequency being a transition frequency between ground levels forming the quantum interference state.

### (Supplementary Note 2)

The quantum interference apparatus described in Supplementary note 1, further comprising:

light detection means for detecting light that has been transmitted through the alkali-metal atomic cell; and

control means for controlling the static magnetic field based on a spectrum of transmitted light corresponding to the light detected by the light detection means so that the fluctuations are suppressed.

### (Supplementary Note 3)

The quantum interference apparatus described in Supplementary note 2, wherein the control means controls the static magnetic field so that the fluctuations fall within a predetermined range.

### (Supplementary Note 4)

The quantum interference apparatus described in Supplementary note 2 or 3, further comprising light generating means for modulating an intensity of the excitation light, wherein

the control means controls a light amount of the excitation light based on a spectrum of transmitted light corresponding to the light detected by the light detection means.

### (Supplementary Note 5)

The quantum interference apparatus described in any one of Supplementary notes 1 to 4, further comprising a light trapping system configured to trap cooled atoms in the alkali-metal atomic cell, the cooled atoms being the alkali-metal atoms.

### (Supplementary Note 6)

The quantum interference apparatus described in any one of Supplementary notes 1 to 5, wherein alkali-metal atoms are at least one of cesium atoms, rubidium atoms, sodium atoms, and potassium atoms.

### (Supplementary Note 7)

An atomic oscillator comprising:

a quantum interference apparatus described in any one of Supplementary notes 1 to 6; and

a mechanism for adjusting an oscillating frequency based on the quantum interference state.

### (Supplementary Note 8)

A control method comprising:

applying excitation light having at least two different frequency components to an alkali-metal atomic cell in which alkali-metal atoms are encapsulated;

detecting light that has been transmitted through the alkali-metal atomic cell, and detecting a CPT resonance by measuring a spectrum of the transmitted light; and

controlling a static magnetic field applied to the alkali-metal atomic cell so that fluctuations of a resonance frequency of the CPT resonance with respect to a magnetic field are suppressed.

### (Supplementary Note 9)

The control method described in Supplementary note 8, wherein the static magnetic field is controlled so that the fluctuations fall within a predetermined range.

### (Supplementary Note 10)

The control method described in Supplementary note 8 or 9, wherein a light amount of the excitation light is controlled based on a spectrum of transmitted light corresponding to the detected light.

### (Supplementary Note 11)

The control method described in Supplementary note 10, wherein a light amount of the excitation light is changed when the CPT resonances overlap each other.

While the disclosure has been particularly shown and described with reference to embodiments thereof, the disclosure is not limited to these embodiments. It will be understood by those of ordinary skill in the art that various changes in form and details may be made therein without departing from the spirit and scope of the present disclosure as defined by the claims.

What is claimed is:

1. A quantum interference apparatus comprising:
a space to which a static magnetic field having a specific direction and a specific strength is applied; and
an alkali-metal atomic cell disposed inside the space and encapsulating alkali-metal atoms therein, wherein
as the static magnetic field is applied to the alkali-metal atomic cell and excitation light having at least two different frequency components is applied thereto, a quantum interference state of the alkali-metal atoms is formed,
among the frequency components of the excitation light, a frequency component that participates in the formation of the quantum interference state is light containing linearly-polarized lights having the same polarization direction as each other, and
the static magnetic field is adjusted so that fluctuations of a resonance frequency with respect to the magnetic field are suppressed, the resonance frequency being a transition frequency between ground levels forming the quantum interference state.

2. The quantum interference apparatus according to claim 1, further comprising:
a light detector configured to detect light that has been transmitted through the alkali-metal atomic cell; and
a control device configured to control the static magnetic field based on a spectrum of transmitted light corresponding to the light detected by the light detector so that the fluctuations are suppressed.

3. The quantum interference apparatus according to claim 2, wherein the control device controls the static magnetic field so that the fluctuations fall within a predetermined range.

4. The quantum interference apparatus according to claim 2, further comprising a light generator configured to modulate an intensity of the excitation light, wherein
the control device controls a light amount of the excitation light based on a spectrum of transmitted light corresponding to the light detected by the light detector.

5. The quantum interference apparatus according to claim 1, further comprising a light trapping system configured to trap cooled atoms in the alkali-metal atomic cell, the cooled atoms being the alkali-metal atoms.

6. The quantum interference apparatus according to claim 1, wherein alkali-metal atoms are at least one of cesium atoms, rubidium atoms, sodium atoms, and potassium atoms.

7. An atomic oscillator comprising:
a quantum interference apparatus according to claim 1; and
a mechanism for adjusting an oscillating frequency based on the quantum interference state.

8. A control method comprising:
applying excitation light having at least two different frequency components to an alkali-metal atomic cell in which alkali-metal atoms are encapsulated;
detecting light that has been transmitted through the alkali-metal atomic cell, and detecting a CPT resonance by measuring a spectrum of the transmitted light; and
controlling a static magnetic field applied to the alkali-metal atomic cell so that fluctuations of a resonance frequency of the CPT resonance with respect to a magnetic field are suppressed.

9. The control method according to claim 8, wherein the static magnetic field is controlled so that the fluctuations fall within a predetermined range.

10. The control method according to claim 8, wherein a light amount of the excitation light is controlled based on a spectrum of transmitted light corresponding to the detected light.

11. The control method according to claim 10, wherein a light amount of the excitation light is changed when the CPT resonances overlap each other.
